(19) United States
(12) Patent Application Publication
(10) Pub. No.: US 2012/0025211 A1
(43) Pub. Date: Feb. 2, 2012

(54) COMPACT SENSOR PACKAGE STRUCTURE

(75) Inventors: TSAN-LIEN YEH, SHIN-CHU (TW); WAN-HUA WU, SHIN-CHU (TW); SZU-CHUAN PANG, SHIN-CHU (TW); CHI-CHANG WU, SHIN-CHU (TW); MING-HUNG HUNG, SHIN-CHU (TW)

(73) Assignee: SIGURD MICROELECTRONICS CORP., SHIN-CHU (TW)

(21) Appl. No.: 13/176,807

(22) Filed: Jul. 6, 2011

(30) Foreign Application Priority Data
Jul. 30, 2010 (TW) 099214623

(51) Int. Cl. H01L 31/12

(52) U.S. Cl. 257/82; 257/E31.103

(57) ABSTRACT

The present invention discloses a compact sensor package structure, which comprises a package body, an LED chip and a sensor chip. The package body has a first room, a second room, a first hole and a second hole. The first and second rooms are independent to each other. The first and second holes interconnect the interiors and the external environments of the first and second rooms. The LED chip is arranged inside the first room, corresponding to the first hole and below the first hole. The LED chip projects light through the first hole. The sensor chip is arranged inside the second room, corresponding to the second hole and above/below the second hole. The sensor chip receives light via the second hole. The present invention features two independent rooms for two chips and prevents interference between the two chips.

### BACKGROUND OF THE INVENTION

1. Field of the Invention

The present invention relates to a package structure, particularly to a compact sensor package structure.

2. Description of the Related Art

Sensors and controllers are basic electronics. In sensation, a sensor normally sends a signal, which is normally in form of light, to a detected object; then the signal, which has carried information, is reflected from the detected object back to the sensor for succeeding processing. Refer to FIG. 1. Considering difference between the physical characteristics of the elements and optimization the performance thereof, a light source chip 10 and a sensor chip 12 are normally fabricated and packaged respectively and then electrically connected by a printed circuit board 14, whereby they can detect an object 16.

For example, a conventional distance sensor has two chips. One is an LED (Light Emitting Diode) chip, and the other one is a light sensor chip. The two chips are fabricated independently beforehand and integrated together afterward. Therefore, the conventional distance sensor has complicated assembly procedures, longer fabrication processes and higher fabrication cost. Besides, the conventional distance sensor has merely a single sensor chip and thus can only detect limited distance. Therefore, it is less likely to apply to all consumer electronic products.

Accordingly, the present invention proposes a compact sensor package structure to overcome the conventional problems.

### SUMMARY OF THE INVENTION

The primary objective of the present invention is to provide a compact sensor package structure, which has two independent rooms respectively accommodating an LED chip and a sensor chip, and which not only has a smaller volume but also prevents the sensor chip from being interfered with by the light emitted by the LED chip, whereby the present invention has improved performance.

To achieve the abovementioned objective, the present invention proposes a compact sensor package structure, which comprises a package body, an LED chip and a sensor chip, wherein the package body has a first room, a second room, a first hole and a second hole, and wherein the first and second rooms are independent to each other, and wherein the first and second holes interconnect the interiors and the external environments of the first and second rooms. The LED chip is arranged inside the first room, corresponding to the first hole and below the first hole. The LED chip projects light through the first hole. The sensor chip is arranged inside the second room, corresponding to the second hole and above/below the second hole. The sensor chip receives light via the second hole.

Below, the embodiments are described in detail in cooperation with the attached drawings to make easily understood the characteristics, technical contents and accomplishments of the present invention.

### BRIEF DESCRIPTION OF THE DRAWINGS

FIG. 1 is a sectional view of a conventional sensor package structure;

FIG. 2 is a sectional view schematically showing a sensor package structure according to a first embodiment of the present invention;

FIG. 3 is a top view schematically showing the sensor package structure according to the first embodiment of the present invention;

FIG. 4 is a sectional view schematically showing a sensor package structure according to a second embodiment of the present invention; and

FIG. 5 is a top view schematically showing the sensor package structure according to the second embodiment of the present invention.

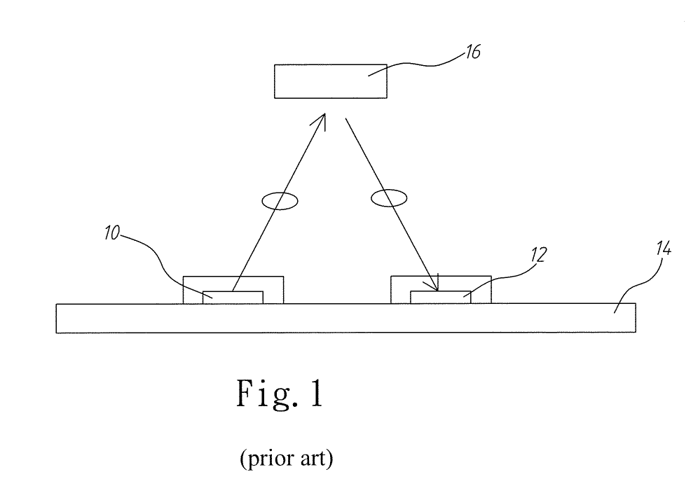

### DETAILED DESCRIPTION OF THE INVENTION

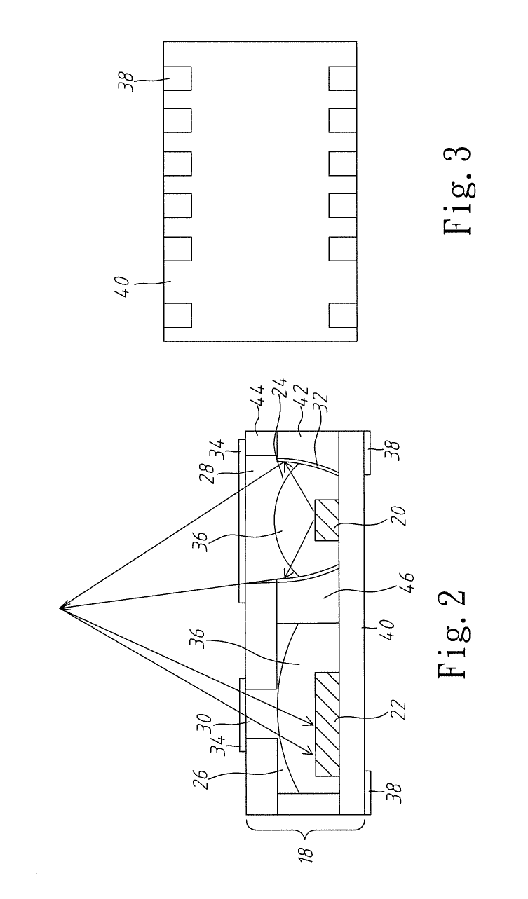

Below is described a first embodiment according to the present invention. Refer to FIG. 2 and FIG. 3. The compact sensor package structure of the present invention comprises a package body 18, an LED chip 20 and a sensor chip 22. The package body 18 has a first room 24 and a second room 26, which are independent to each other. The package body 18 also has a first hole 28 and a second hole 30. The first hole 28 interconnects the interior and the external environment of the first room 24. The second hole 30 interconnects the interior and the external environment of the second room 26. The second hole 30 is an opening for receiving and focusing light. The second hole 30 is only for receiving a light having a specified range of wavelengths and coming from a specified range of reflective angles lest noise interfere with the sensor chip 22. The inner surface of the first room 24 has a very smooth focusing reflection layer 32. The LED chip 20 is arranged inside the first room 24, corresponding to the first hole 28 and below the first hole 28. The focusing reflection layer 32 focuses the scattered light emitted by the LED chip 20 into a light, and the light is projected through the first hole 28 to an object. The sensor chip 22 is arranged inside the second room 26, corresponding to the second hole 30 and below the second hole 30, and the sensor chip 22 receives the light reflected from the object via the second hole 30.

In order to protect the chips, transparent plates 34 are respectively arranged over the first and second holes 28 and 30. Further, transparent plastic resins 36 are respectively filled into the first and second rooms 24 and 26 to encapsulate the LED chip 20 and the sensor chip 22. A plurality of I/O pins 38 is arranged along the bottom of the package body 18 for meeting design requirement.

To meet design requirement, the transparent plates 34 and the transparent resins 36 can be omitted.

The present invention is characterized in packaging an LED chip 20 and a sensor chip 22 in an identical package body 18. Thereby, the present invention has smaller volume and lower cost. The package body 18 further comprises a base 40 and a sidewall 42. The base 40 may be in form of a substrate or a metallic lead frame. The sidewall 42 may be made of a plastic material. The base 40 has I/O pins 38 in the bottom thereof. The sidewall 42 rises vertically from the rim of the base 40 and cooperates with the base 40 to form a basin. The base 40 and the sidewall 42 may be fabricated into a one-piece component with an injection-molding process. Alternatively, the sidewall 42 is bonded to the base 40 to form the basin. A cover 44 is arranged over the sidewall 42 to cover the basin. The cover 44 has the first and second holes 28 and 30. The cover 44 cooperates with the base 40 and the sidewall 42 to form an accommodation space. A separator 46 is arranged in an appropriate position of the accommodation room, whereby the first and second holes 28 and 30 are respectively located at two sides of the separator 46. The separator 46 is vertically joined to the base 40 and the cover 44, partitioning the accommodation space into the first and second rooms 24 and 26. The focusing reflection layer 32 is arranged on the base 40, the side wall 42 and the separator 46 of the first room 24. In the first room 24, the LED chip 20 is arranged on the base 40 and below the first hole 28. In the second room 26, the sensor chip 22 is arranged on the base 40 and below the second hole 30. As the first room 24 and the second room 26 are independent to each other, the LED chip 20 would not interfere with the sensor chip 22 directly. Thereby, the present invention has improved performance. The two transparent resins 36 are respectively filled into the first room 24 and the second room 26 to encapsulate the LED chip 20 and the sensor chip 22.

The LED chip 20 emits scattered light to the focusing reflection layer 32. The focusing reflection layer 32 reflects the scattered light, and the transparent resin 36 focuses the reflected light to the first hole 28, and the focused light is projected to an object through the first hole 28 and the transparent plate 34. The object reflects the projected light. The sensor chip 22 receives the light reflected by the object through the transparent plate 34, the second hole 30 and the transparent resin 36.

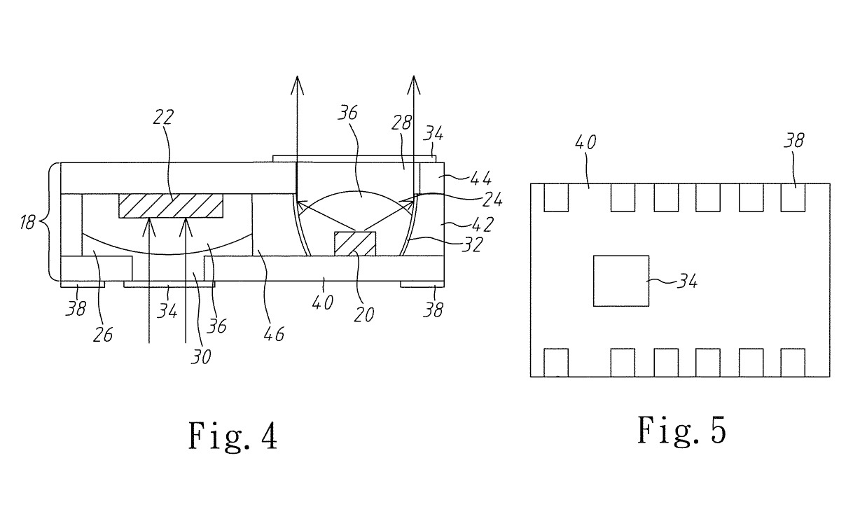

In the first embodiment, the light projection path and the light-receiving path are at the same side. In a second embodiment, the light projection path and the light-receiving path are respectively at opposite sides. Refer to FIG. 4 and FIG. 5 for the second embodiment.

In the second embodiment, the compact sensor package structure of the present invention comprises a package body 18, an LED chip 20 and a sensor chip 22. The package body 18 has a first room 24 and a second room 26, which are independent to each other. The package body 18 also has a first hole 28 and a second hole 30. The first hole 28 interconnects the interior and the external environment of the first room 24. The second hole 30 interconnects the interior and the external environment of the second room 26. The second hole 30 is only for receiving a light having a specified range of wavelengths and coming from a specified range of reflective angles lest noise interfere with the sensor chip 22. The inner surface of the first room 24 has a very smooth focusing reflection layer 32. The LED chip 20 is arranged inside the first room 24, corresponding to the first hole 28 and below the first hole 28. The focusing reflection layer 32 focuses the light emitted by the LED chip 20 into a light beam, and the light beam is projected through the first hole 28 to an object. The sensor chip 22 is arranged inside the second room 26, corresponding to the second hole 30 and above the second hole 30, and the sensor chip 22 receives the light reflected from the object via the second hole 30.

In order to protect the chips, transparent plates 34 are respectively arranged over the first and second holes 28 and 30. Further, transparent plastic resins 36 are respectively filled into the first and second rooms 24 and 26 to encapsulate the LED chip 20 and the sensor chip 22. A plurality of I/O pins 38 is arranged along the bottom of the package body 18 for meeting design requirement.

Similarly, the transparent plates 34 and the transparent resins 36 can be omitted to meet design requirement in the second embodiment.

In the second embodiment, the LED chip 20 and the sensor chip 22 are also packaged in an identical package body 18 to decrease volume and reduce cost. The package body 18 further comprises a base 40 and a sidewall 42. The base 40 may be in form of a substrate or a metallic lead frame. The sidewall 42 may be made of a plastic material. The base 40 has the second hole 30. The base 40 also has I/O pins 38 in the bottom thereof. The sidewall 42 rises vertically from the rim of the base 40 and cooperates with the base 40 to form a basin. The base 40 and the sidewall may be fabricated into a one-piece component with an injection-molding process. Alternatively, the sidewall 42 is bonded to the base 40 to form the basin. A cover 44 is arranged over the sidewall 42 to cover the basin. The cover 44 has the first hole 28. The cover 44 cooperates with the base 40 and the sidewall 42 to form an accommodation space. A separator 46 is arranged in an appropriate position of the accommodation room, whereby the first and second holes 28 and 30 are respectively located at two sides of the separator 46. The separator 46 is vertically joined to the base 40 and the cover 44, partitioning the accommodation space into the first and second rooms 24 and 26. The focusing reflection layer 32 is arranged on the base 40, the side wall 42 and the separator 46 of the first room 24. In the first room 24, the LED chip 20 is arranged on the base 40 and below the first hole 28. In the second room 26, the sensor chip 22 is arranged on the cover 44 and above the second hole 30. As the first room 24 and the second room 26 are independent to each other, the LED chip 20 would not interfere with the sensor chip 22 directly. Thereby, the present invention has improved performance. The two transparent resins 36 are respectively filled into the first room 24 and the second room 26 to encapsulate the LED chip 20 and the sensor chip 22.

The light projection way and the light receiving way of the second embodiment are similar to those of the first embodiment and will not repeat herein.

In conclusion, the present invention features small volume and prevents the sensor chip from being directly interfered with by the light emitted by the light source chip. Therefore, the present invention has improved performance.

The embodiments described above are only to exemplify the present invention but not to limit the scope of the present invention. Any equivalent modification or variation according to the characteristics, technical contents or spirit of the present invention is to be also included within the scope of the present invention.

What is claimed is:

1. A compact sensor package structure comprising
a package body having a first room, a second room, a first hole and a second hole, wherein said first room and said second room are independent to each other, and wherein said first hole interconnects interior and external environment of said first room, and wherein said second hole interconnects interior and external environment of said second room;
a light emitting diode (LED) chip arranged inside said first room and corresponding to said first hole, and projecting light through said first hole; and
a sensor chip arranged inside said second room and corresponding to said second hole, and receiving said light via said second hole.

2. The compact sensor package structure according to claim 1, wherein a focusing reflection layer is arranged on an inner surface of said first room to focus scattered light emitted by said LED chip into said light beam and project said light through said first hole.

3. The compact sensor package structure according to claim 1 further comprising two transparent resins that are respectively filled into said first room and said second room to encapsulate said LED chip and said sensor chip.

4. The compact sensor package structure according to claim 3, wherein said two transparent resins comprise a plastic material.

5. The compact sensor package structure according to claim 1, wherein a plurality of I/O pins is arranged in a perimeter of a bottom of said package body.

6. The compact sensor package structure according to claim 1, wherein two transparent plates are respectively arranged over said first hole and said second hole to cover said first hole and said second hole.

7. The compact sensor package structure according to claim 1, wherein said package body further comprises
a base;
a sidewall vertically rising from a rim of said base and cooperating with said base to form a basin;
a cover arranged over said sidewall to cover said basin, cooperating with said base and said sidewall to form an accommodation space, and having said first hole and said second hole; and
a separator arranged in said accommodation space to make said first hole and said second hole respectively at two sides of said separator, vertically joined to said base and said cover to partition said accommodation space into said first room and said second room, wherein said LED chip is arranged on said base in said first room and below said first hole, and wherein said sensor chip is arranged on said base in said second room and below said second hole.

8. The compact sensor package structure according to claim 1, wherein said package body further comprises
a base having said second hole;
a sidewall vertically rising a rim of said base and cooperating with said base to form a basin;
a cover arranged over said sidewall to cover said basin, cooperating with said base and said sidewall to form an accommodation space, and having said first hole; and
a separator arranged in said accommodation space to make said first hole and said second hole respectively at two sides of said separator, vertically joined to said base and said cover to partition said accommodation space into said first room and said second room, wherein said LED chip is arranged on said base in said first room and below said first hole, and wherein said sensor chip is arranged on said cover in said second room and above said second hole.

9. The compact sensor package structure according to claim 7, wherein said base is in form of a substrate or a metallic lead frame.

10. The compact sensor package structure according to claim 8, wherein said base is in form of a substrate or a metallic lead frame.

11. The compact sensor package structure according to claim 7, wherein said sidewall comprises a plastic material.

12. The compact sensor package structure according to claim 8, wherein said sidewall comprises a plastic material.
